(19) United States
(12) Patent Application Publication
(10) Pub. No.: US 2019/0357380 A1
(43) Pub. Date: Nov. 21, 2019

(54) APPARATUSES TO VENT AIR THERETHROUGH

(71) Applicant: NOKIA SOLUTIONS AND NETWORKS OY, Espoo (FI)

(72) Inventors: Marc Armah PREUSS, Ottawa (CA); Peter John SERJAK, Ottawa (CA)

(73) Assignee: Nokia Solutions and Networks Oy

(21) Appl. No.: 15/984,118

(22) Filed: May 18, 2018

(51) Int. Cl. H05K 7/20; G06F 1/18; G06F 1/20

(52) U.S. Cl. CPC H05K 7/2019; G06F 1/20; G06F 1/181

(57) ABSTRACT

An apparatus including a first section having a first plurality of card slots, a second section having a second plurality of card slots, a middle section disposed between the first section and the second section, and a channel structure in the middle section configured to vent air out of the apparatus.

### TECHNICAL FIELD

Embodiments are related to cooling systems for chassis apparatuses. More particularly, embodiments described herein relate to chassis apparatus and air flow methods for chassis apparatuses to draw air in through front and/or rear faceplates and exhaust air upwards through a middle section of the chassis apparatuses.

### SUMMARY

In light of the present need for an efficient cooling system for a chassis apparatus, a brief summary of various exemplary embodiments is presented. Some simplifications and omissions may be made in the following summary, which is intended to highlight and introduce some aspects of the various exemplary embodiments, but not to limit the scope of the invention. Detailed descriptions of a preferred exemplary embodiment adequate to allow those of ordinary skill in the art to make and use the inventive concepts will follow in later sections.

Embodiments include an apparatus including a first section having a first plurality of card slots, a second section having a second plurality of card slots, a middle section disposed between the first section and the second section, and a channel structure in the middle section configured to vent air out of the apparatus.

The channel structure may be configured to vent air from a lower portion of the middle section to an upper portion of the middle section.

The channel structure may be configured to pull air out of the first section and the second section.

The first section may include a first plurality of cards and the second section includes a second plurality of cards. The first plurality of cards may have front faces with vents therein to receive ambient air. Different cards of the first plurality of cards may vent different volumes of air therethrough.

The apparatus may include a midplane in the middle section, wherein the first plurality of cards are connected to the second plurality of cards through the midplane.

The first plurality of cards may not be connected to the second plurality of cards through the middle section.

Embodiments also include a chassis apparatus including a first portion of the chassis apparatus configured to draw in air in a first direction, a second portion of the chassis apparatus configured to draw in air in a second direction substantially opposite to the first direction, and a third portion of the chassis apparatus configured to receive the air from the first direction and the second direction and channel the air in a third direction substantially perpendicular to the first direction and the second direction.

The third portion may include a channel structure configured to receive the air and exhaust it in the third direction. The first portion may be configured to hold a first plurality of cards.

The first plurality of cards may each have first vents configured to receive ambient air to cool fronts of the first plurality of cards.

The second portion may be configured to hold a second plurality of cards. The second plurality of cards may each have second vents configured to receive ambient air to cool fronts of the plurality of cards. The second plurality of cards may have optical transceivers disposed on respective faces thereof and each optical transceiver receives substantially a same amount of air.

The third portion may include a channel structure having a plurality of perforations configured to receive air from the first direction and the second direction and direct it upwards.

The chassis may include a wire mesh disposed in the third portion to connect electrical components in the first portion to electrical components in the second portion.

Embodiments may also include an apparatus including a first section having a first plurality of card slots, a second section having a second plurality of card slots, a middle section disposed between the first section and the second section, and a channel structure in the middle section configured to vent air out of the apparatus, wherein the middle section includes an air mover apparatus configured to draw air out of the channel structure.

The air mover apparatus may be at least one centrifugal blower fan.

Air may be vented through the second plurality of card slots in a first direction and the air mover apparatus may vent air out of the channel structure in a second direction substantially opposite the first direction.

The air mover apparatus may be at least one axial fan.

Air may be vented through the first plurality of card slots in a first direction, and the air mover apparatus may vent air out of the channel structure in a second direction substantially perpendicular to the first direction.

The channel structure may include a first plurality of air slots corresponding to the first section having a plurality of card slots. A quantity of the first plurality of air slots may be equal to a quantity of card slots in the first section. A quantity of the second plurality of air slots may be equal to a quantity of card slots in the second section.

The second plurality of air slots may vary in width from a top to a bottom of the channel structure.

The first plurality of air slots may vary in open area from a top to a bottom of the channel structure.

The channel structure includes a second plurality of air slots corresponding to the second section having a plurality of card slots.

The air mover apparatus may be configured to pull air across front faces of the first plurality of cards and air across front faces of the second plurality of cards.

Embodiments also include a system that includes at least one chassis apparatus including a first section having a first plurality of card slots, a second section having a second plurality of card slots, a middle section disposed between the first section and the second section, and a channel structure in the middle section configured to vent air out of the apparatus, ductwork connected to the at least one chassis apparatus, an air mover apparatus configured to draw air out of the channel structure and through the ductwork, the air mover apparatus disposed in a different location than the chassis apparatus, and a communication connection between the air mover apparatus and the at least one chassis apparatus.

The at least one chassis apparatus may include a plurality of chassis apparatuses stacked in series on top of one another with their middle sections aligned.

The channel structure may include a first plurality of air slots corresponding to the first section having a plurality of card slots.

A quantity of the first plurality of air slots may be equal to a quantity of card slots in the first section. A quantity of the second plurality of air slots may be equal to a quantity of card slots in the second section. The second plurality of air slots may vary in width from a top to a bottom of the channel structure.

The first plurality of air slots may vary in open area from a top to a bottom of the channel structure.

The channel structure may include a second plurality of air slots corresponding to the second section having a plurality of card slots.

### BRIEF DESCRIPTION OF THE DRAWINGS

In order to better understand various exemplary embodiments, reference is made to the accompanying drawings, wherein:

FIG. 1 illustrates a top view of a chassis apparatus in accordance with embodiments described herein;

FIG. 2 illustrates a side view of a chassis apparatus in accordance with FIG. 1;

FIG. 3 illustrates air flow through a top view of a chassis apparatus in accordance with FIG. 1;

FIG. 4 illustrates air flow through a side view of a chassis apparatus in accordance with FIG. 2; and

FIG. 5 illustrates a front or rear face of a chassis apparatus in accordance with embodiments described herein;

FIG. 6 illustrates a chassis apparatus having blower air movers in accordance with embodiments described herein;

FIG. 7 illustrates a centrifugal blower fan in accordance with FIG. 6;

FIG. 8 illustrates a perforated channel structure to balance airflow throughout the system in accordance with embodiments described herein;

FIGS. 9A and 9B illustrates examples of a multi blower fan trays used in either a cylindrical center channel structure or a rectangular channel structure in accordance with embodiments described herein;

FIG. 10 illustrates a multi-shelf chassis apparatus in accordance with embodiments described herein;

FIG. 11 illustrates an axial air mover in conjunction with a chassis apparatus according to embodiments described herein.

FIGS. 12A and 12B illustrate examples of fan trays with cylindrical and rectangular center channels in accordance with FIG. 11;

FIG. 13 illustrates stackable axial blower chassis apparatuses in accordance with embodiments described herein;

FIG. 14 illustrates a chassis system including a single chassis apparatus driven by a central fan unit in accordance with embodiments described herein;

FIG. 15 illustrates a stackable variant of a chassis apparatus driven by a central fan unit in accordance with embodiments described herein;

FIGS. 16A and 16B illustrate cross-sectional views of a related art direct front to back cooling chassis apparatus 1600; and

FIG. 17 illustrates a cross-sectional view of a related art exhaust configuration of a chassis apparatus

### DETAILED DESCRIPTION

It should be understood that the figures are merely schematic and are not drawn to scale. It should also be understood that the same reference numerals are used throughout the figures to indicate the same or similar parts.

The descriptions and drawings illustrate the principles of various example embodiments. It will thus be appreciated that those skilled in the art will be able to devise various arrangements that, although not explicitly described or illustrated herein, embody the principles of the invention and are included within its scope. Furthermore, all examples recited herein are principally intended expressly to be for pedagogical purposes to aid the reader in understanding the principles of the invention and the concepts contributed by the inventor(s) to furthering the art, and are to be construed as being without limitation to such specifically recited examples and conditions. Additionally, the term, “or,” as used herein, refers to a non-exclusive or (i.e., and/or), unless otherwise indicated (e.g., “or else” or “or in the alternative”). Also, the various embodiments described herein are not necessarily mutually exclusive, as some embodiments can be combined with one or more other embodiments to form new embodiments. Descriptors such as “first,” “second,” “third,” etc., are not meant to limit the order of elements discussed, are used to distinguish one element from the next, and are generally interchangeable. Values such as maximum or minimum may be predetermined and set to different values based on the application. When steps of manufacture, process of using, or other method steps are described or claimed, the order of steps given is not constrained by the order presented, and may vary. Terms such as “below,” “above,” “right,” and “left,” may be used for relative orientation of a device or apparatus as illustrated in a figure. If an apparatus or component of a figure may be rotated and still function in a similar manner to what is described, the directional terms are not limited to the orientation illustrated in a particular figure. “Below” when rotated may become “right,” or “left” or “above.” The same holds true for the other directional indicators.

Chassis apparatuses can have functional cards that plug into the front and back thereof. Related art chassis apparatus designs have been designed to pull in air from a front or bottom of the chassis apparatus, underneath functional cards. Cool air comes into a chassis apparatus through the front or bottom, gets heated by the equipment, and is exhausted out of the back into a hot aisle.

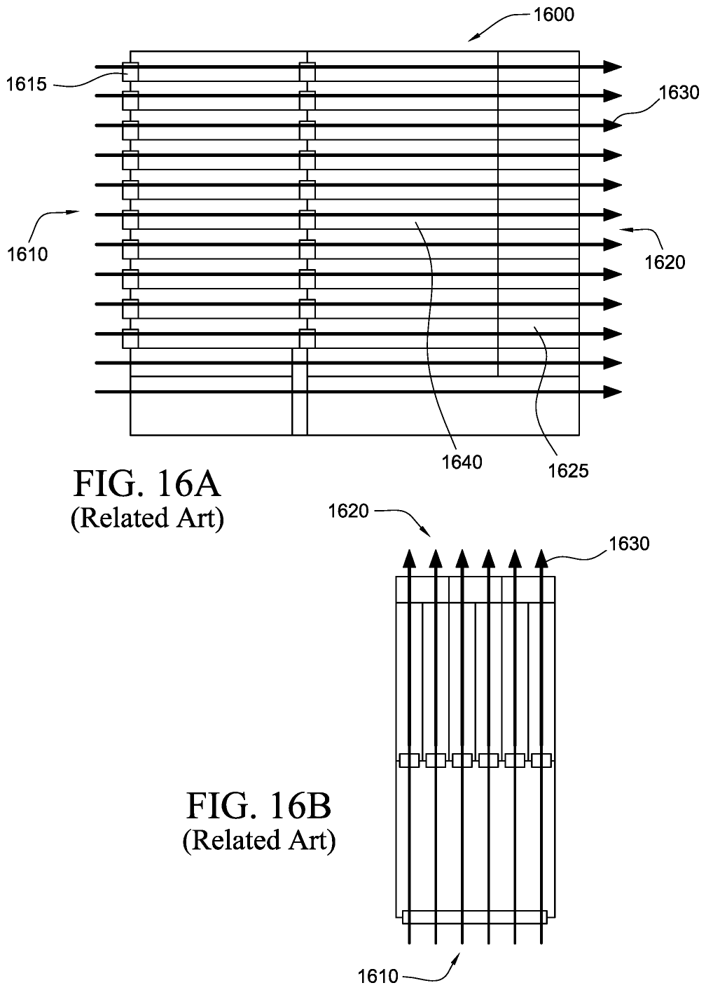

FIGS. 16A and 16B illustrate cross-sectional view of a related art direct front to back cooling chassis apparatus 1600. As illustrated in FIGS. 16A and 16B, optics 1615 such as optical transceivers may be disposed only on a front side 1610 of the chassis apparatus 1600. A second group of cards 1640 such as fabric cards without rear access may be disposed toward a rear portion 1620 of the chassis apparatus 1600. A wall of fan trays 1625 cover the rear portion 1620, such that no fiber access is possible on rear cards 1640 of a direct front to back cooling chassis. In a front to back cooling air flow such as this one, optics 1615 near the air entry point at the front side 1610 are cooled by external air, but electronic components such as the fabric cards 1640 further along the path towards the back of the chassis 1600 are only acted on by preheated air 1630 that is drawn out of the rear of a chassis.

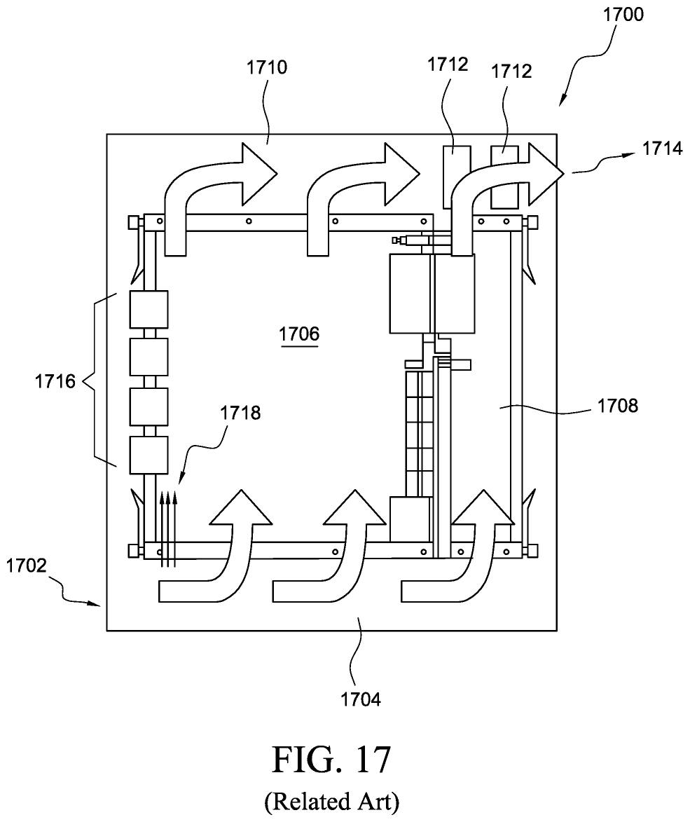

FIG. 17 illustrates a cross-sectional view of a related art bottom to top exhaust configuration of a chassis apparatus 1700. Vertical cards 1706 may be stacked in an arrangement with space between each card. Alternatively, cards may be stacked horizontally. The chassis apparatus 1700 may have a bottom plenum 1704 that includes a plurality of airflow director modules (not illustrated) and an upper plenum 1710 also having a plurality of airflow director modules (not illustrated). The plurality of airflow modules may be stacked together to form a plurality of air duct channels. In one configuration, air may be drawn into the chassis apparatus 1700 through one or more air inlet ports 1702. Each air duct channel has an airflow inlet to receive airflow supplied at the air inlet port 1702 adjacent the bottom plenum 1704 and an airflow outlet to exhaust airflow passing through the duct channel at an outlet side of the bottom plenum 1704 across one or more cards 1706. A card 1706 may have a plurality of optical elements 1716 disposed at a front thereof. The airflow outlets on the bottom plenum 1704 may be configured in a grid having at least two rows and two columns.

Air enters the chassis apparatus 1700 at the air inlet port 1702 at the lower front into the bottom plenum 1704 and turns ninety degrees upward. Airflow may be distributed across a bottom edge of a card 1706 and a rear transition module (RTM) 1708. As air passes across hot components on card 1706 and RTM 1708, heat is carried upwards and the components at an upper end of the card 1706 will receive additional heat from lower components on the card 1706 via the warm air flowing upward. This may be true for a stack of optical elements 1716. An upper optical element 1716 in a stack thereof may be warmed a to a considerable higher temperature than an optical element at a bottom of the stack optical elements 1716.

In addition, the upper optics air flow is shadowed by the optics below. In this arrangement, cool air 1718 from below may cool the lowest positioned optics in the optical elements stack 1716, but the lowest positioned optic not only pre-heats the incident air to the optics directly above, but also impedes the cooling air from hitting, or cooling, the optics above. After progressively heating next higher elements, the warmest air exits a subrack at the top. The warm air is drawn into the upper plenum 1710, turns ninety degrees, and is exhausted by fans 1712 out of a rear of the chassis apparatus 1700 via one or more air outlet ports 1714. The hot air that has accumulated near the top of the cards 1706 is exhausted towards the rear of the chassis apparatus 1700 into a hot aisle.

Related art designs may also include horizontal and vertical fans on fan trays that cover a whole back of the chassis apparatus 1700. This may provide a cooling solution but does not allow optical connections to be made on the rear cards, such as fabric cards. As described herein, optical connections on fabric or other rear cards allow multiple chassis apparatuses to be cabled together.

A chassis apparatus may be configured to hold various electronic components in the form of line cards, boards, server blades, and the like. A chassis apparatus in accordance with embodiments described herein may be designed to accept electronic cards plugged into the front and/or the rear of the chassis apparatus. The chassis apparatus is designed to provide cooling for the cards and other electronic components in the system. Embodiments described herein include a new airflow method and a physical realization thereof.

Examples of chassis apparatus implementations include large router/switch, server blade, and other systems that hold computer, electrical, and/or optical components including multiple line cards to make an electrical connection to multiple fabric cards of a router/switch dataplane. This is often accomplished by connecting both card types to a fixed-in-place electronic printed circuit board (“PCB”), wired midplane or backplane, or by an orthogonal-direct or orthogonal-midplane connection between each line card and all fabric cards.

A cooling design for a chassis apparatus according to embodiments described herein includes the ability to host optical transceivers or other electrical components on faces and rear faces of the cards to provide cable or fiber access thereto. Air flow is pulled in through the faces of the cards individually, thus cooling the optical transceivers or other electrical components with ambient (cool) air. In embodiments described herein, different types of cards such as line and fabric cards may be disposed close enough together to allow a very short, low-loss electrical connection between an end point of the front card and an end point of the rear card.

Embodiments described herein include a chassis apparatus where a first group of cards such as “line” cards may be plugged into card slots in the front of a chassis apparatus, a second group of cards such as “fabric” cards may be plugged into card slots at a rear of the chassis apparatus, and an air channel is disposed between the front and rear portions of the chassis apparatus. According to embodiments described herein, air may be drawn in through front and rear faces or fronts of the cards and exhausted out through the top of the chassis apparatus via a vertical air channel (e.g., chimney). The exhausted air may be piped into the ceiling or into ductwork that may take it to a different area. In this manner, all of the optics at the front faces receive substantially the same ambient cool air across their faces.

By providing optical transceivers at both ends of a chassis apparatus, a system may provide twice the number of optical links in a same form factor of a traditional system such as the direct front-back cooling method in which optical links may only be placed on a front of a chassis 1600.

Electrical or optic connections may be made between a first group of cards and a second group of cards. In other embodiments, both groups of cards may function independently of each other and not be electrically or optically connected. The connection between groups of cards may be made with a PCB-based, wired, or optical midplane that provides a short, low-loss connection between the sections.

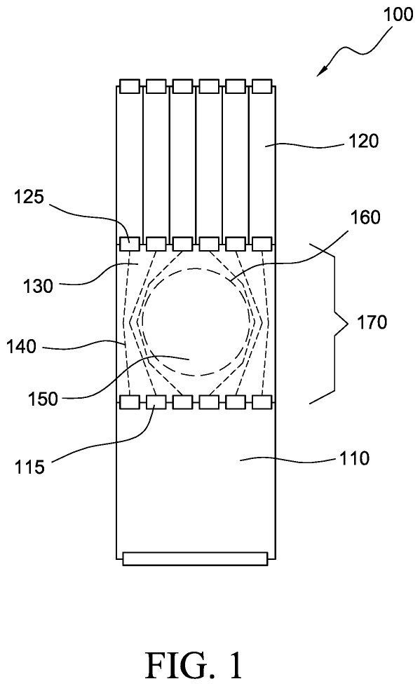

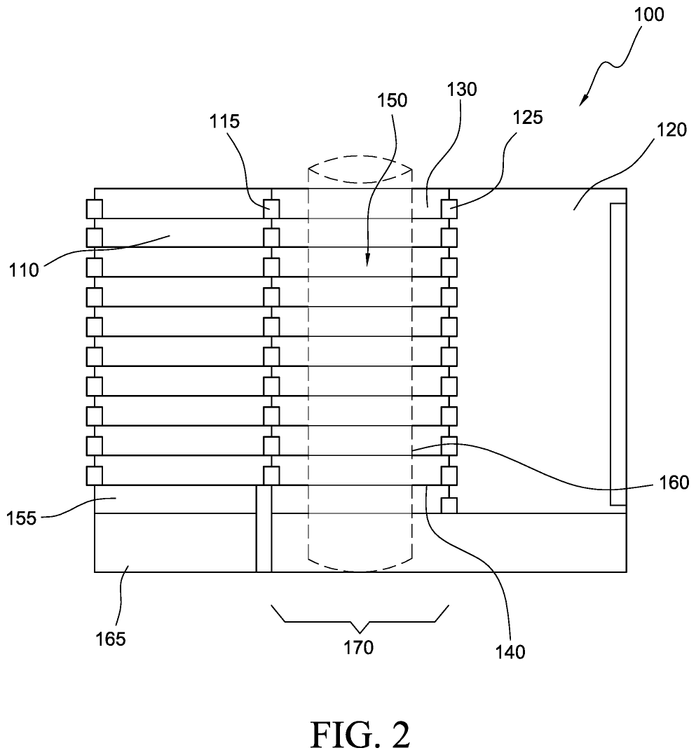

FIG. 1 illustrates a top view and FIG. 2 illustrates a side view of a chassis apparatus 100 in accordance with embodiments described herein. As illustrated in FIGS. 1 and 2, first cards 110 in a horizontal stack orientation may plug into slots in a front of the chassis apparatus 100. Second cards 120 in a vertical stack orientation may plug into slots in a rear of the chassis apparatus 100. Signals between the first cards 110 and the second cards 120 may be connected via a horizontal stack of midplanes 130. The first cards 110 may connect to the midplane 130 via first connectors 115. The rear second cards 120 may connect to the midplane 130 via second connectors 125. Each midplane 130 may be composed of PCB material having electrical traces 140 such as waveguides embedded in a PCB or a wire mesh with connectors (i.e., “wired” midplane). A characteristic of the midplane 130 is a hollow section 150 in the middle of midplanes 130. As the midplanes 130 are stacked horizontally in the inner-part of the chassis apparatus 100, a stack of hollow sections 150 make way for a channel structure 160 that extends through a middle section 170 of the chassis apparatus 100. This channel structure 160 is depicted as a cylindrical stack of hollow sections 150 in FIG. 2 but may take any shape (rectangular, square, polygonal, etc.) as may be implemented by one skilled in the art. As illustrated in FIG. 2, the chassis apparatus 100 may also include control cards 155 and a power supply 165 to control operations of the chassis apparatus components. First cards 110 which may be line cards may be compatible with other systems such as front to back systems, illustrated in FIG. 16, for example.

While a traditional chassis apparatus implementation such as a router/switch may include electrical connectors through the middle section 170, this may not always be the case. When no communication is enabled from a front first group of cards 110 to a rear second group of cards 120, the middle section 170 may be devoid of electrical connections, and merely provide the channel structure 160 to vent air upwards. The channel structure 160 may be a material such metal or plastic, and may have a plurality of perforations formed therein to receive air from the front and rear sections of the chassis apparatus 100.

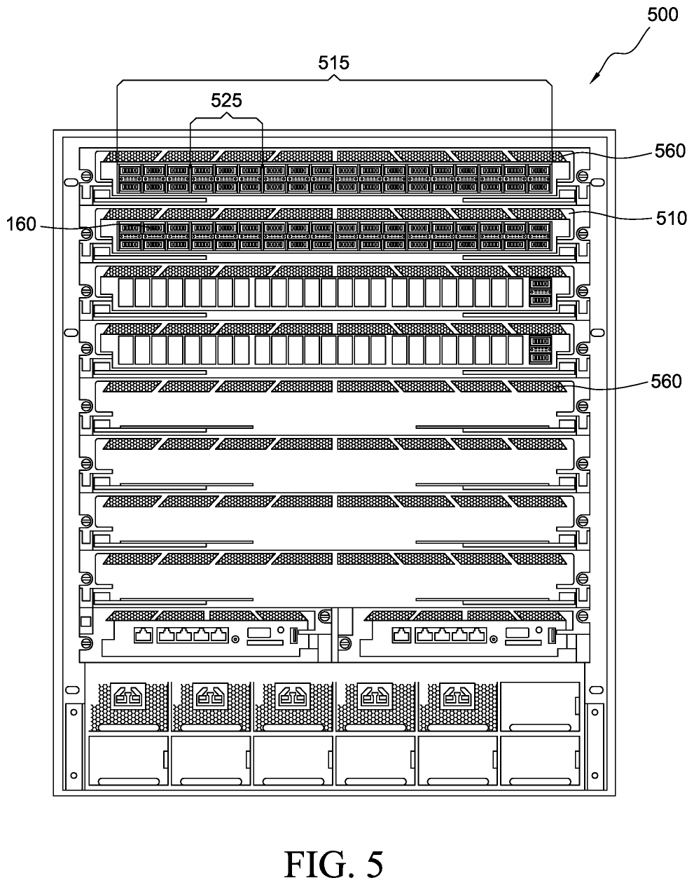

Both the first cards 110 and second cards 120 can host optical transceivers or other electronic connections on their respective faceplates (illustrated in FIG. 5). The first cards 110 and second cards 120 may be positioned close together with a short section of low-loss midplane 130 separating them.

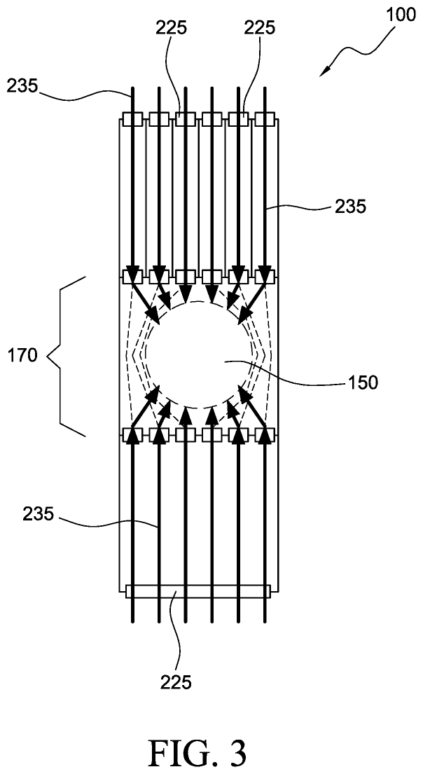

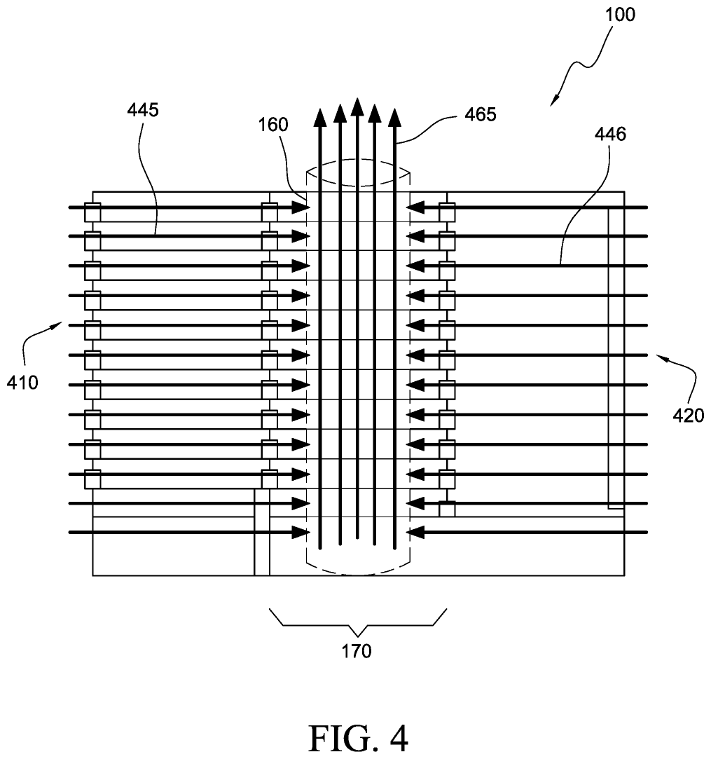

FIGS. 3 and 4 illustrate chassis apparatus airflow in accordance with FIGS. 1 and 2. As illustrated, electrical components such as optical transceivers 225 on both “line” card and “fabric” cards will have vented air 235 passing over them because the air is drawn from the front and rear of the chassis apparatus 100. Note that front first 110 and rear second 120 cards, which may be “line” cards and “fabric” cards may be designed with air vents or perforations in their faceplates that allow air to be taken in, as illustrated in FIG. 5. Once the vented air 235 passes over outer and inner components of a card, it enters the middle section 170 where it is pulled into the channel structure 160 and vented out of the top of the chassis apparatus 100.

In an orthogonal direct system, one group of cards may be oriented vertically and another horizontally, but embodiments described herein are not limited thereto. Chassis apparatus components and functionalities may vary such that sets of vertical cards may be disposed in a front section or rear section and sets of horizontal cards may be likewise distributed. Such dual configurations of cards may double a possible bandwidth from a chassis apparatus that only includes cards in one locale thereof. According to embodiments described herein, because front and back sections each have optical and other ports on faces of the cards, multiple chassis apparatus may be stacked end to end. Also, because air is vented through the channel structure 160, multiple chassis apparatus may be stacked one on top of another and air vented out of the channel structure 160 of both chassis apparatus. Such multiple arrangements may increase the efficiency of floor space.

Embodiments described herein take advantage of the flow of hot air that naturally accumulates upwards. Because air becomes progressively hotter as it rises, less power may be used to exhaust air out of the middle section 170. Taking advantage of natural air flows may decrease the power requirements of the chassis apparatus 100 described herein, because less powerful air movers may be used to draw the air out of the channel structure 160.

Various air movers may be used to draw air out of the channel structure 160 and positioned at several locations of the middle section 170. For example, fans may be placed at a top of the chassis apparatus or fans may be placed at several locations between a top of the chassis apparatus 100 and the middle thereof. The midplane 130 may be a PCB or may be a wire mesh connecting front cards and rear cards. The wires may be tied down to certain points in the chassis apparatus. A diameter of the channel structure 160 may have various lengths and be tailored to release different amounts of heat depending on the heat generation in the chassis apparatus 100.

The chassis apparatus 100 may encompass many electronic devices including a router. When not configured as a router, front first cards 110 may not communicate with rear second cards 120. Embodiments described herein may include standalone cards such as server blades or any other type of board grouped together in one section of the chassis apparatus 100. Though components such as server blades may often be disposed in separate housings, multiple server blades may be stacked together in the chassis apparatus 100 to make use of more efficient power distribution and a centralized fan. If the front cards need not talk to the back, the middle section 170 may be provided without a midplane yet providing cooling as described herein through the channel structure 160. When there is no communication from front cards to back cards, a control midplane may be used to control the separated cards in the chassis apparatus 100.

As illustrated in FIG. 4, according to embodiments described herein, the chassis apparatus 100 with two sets of cards is created to receive cold air. A first front 410 facing one direction receives air across first card faces in one air flow direction 445 towards the middle section 170 of the chassis apparatus 100. A second front 420 facing an opposite direction receives air across second card faces in a second air flow direction 446 towards the middle section 170 of the chassis apparatus 100 in a second air flow direction, substantially opposite the first flow direction. The air received in the first flow direction 445 and the air received in the second flow direction 446 are vented through holes in the channel structure 160 and joined together in the channel structure 160 and routed upwards in a third direction 465 that is substantially perpendicular to the first and second directions. Related art chassis apparatus systems channel air out of the back of a chassis apparatus into a hot aisle.

FIG. 5 illustrates a connection side 500 of a chassis apparatus 100 in accordance with embodiments described herein. The connection side 500 may be a front or rear view of the chassis apparatus 100. The connection side 500 illustrated in FIG. 5 may have slots reserved for up to eight cards 510 such as horizontal cards but is not limited thereto. An example of a card 510 may be a card configured with six groups 515 of input/output optical ports 525. Above each group 515 of optical ports 525 are a plurality of air vents 560 that are designed to pull air across faces of the cards 510 and directed to the internal air channel. Though illustrated horizontally, cards 510 of the connection side 500 may be arranged to have vertically oriented line cards, fabric cards, server blades, or other electronics disposed on a card within a card slot

Because air is routed through the middle portion of the chassis apparatus 100 and the temperatures of all of the optics may be kept low, the clock speed of electronic components within the chassis apparatus 100 increases. With cooler temperatures, more powerful electronics may be used. Without the effective cooling system described herein, a chassis apparatus architecture limits the amount of optical ports. Front entry of air is beneficial to expand the number of ports that may be used. With previous cooling designs optical links fail with rising heat that is not vented across the faces of the boards that builds up within a middle of a chassis apparatus. Embodiments described herein bring cold air across each line card through the vents 560, such that all optical links or other devices may be cooled at the front or back of the chassis apparatus 100 without the pre-heating effect present in the related art. Air flow is pulled in through the front face of the cards individually, thus cooling the optical transceivers with ambient (cool) air. As such, each optical transceiver receives substantially the same amount of air.

Several embodiments may be implemented to move air through a central portion of a chassis apparatus externally thereof.

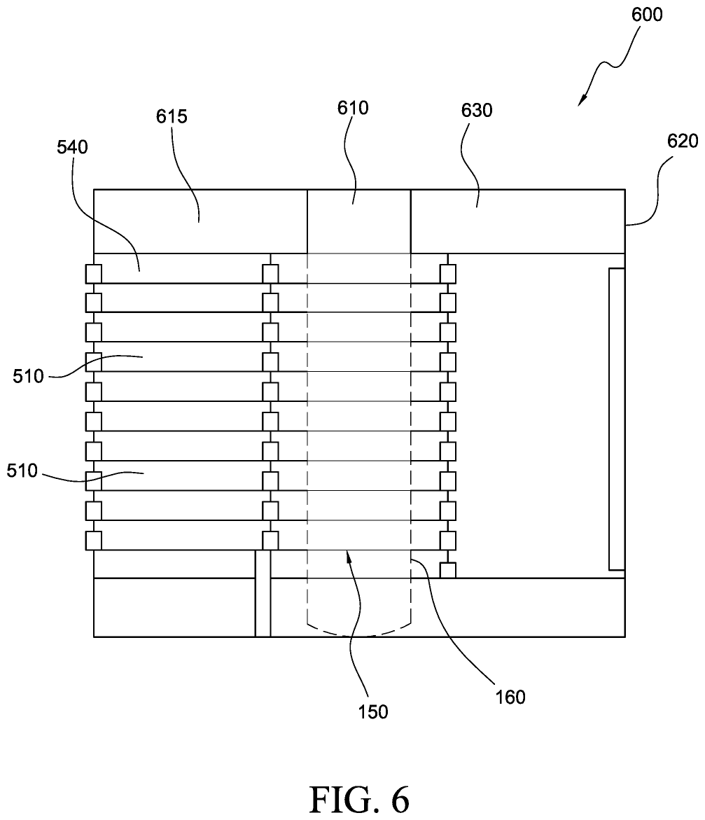

FIG. 6 illustrates redundant powered centrifugal blower fans located at a top of a chassis apparatus. One or a plurality of centrifugal blower fans are included along with air flow balancing features within a center of a chassis apparatus that are configured to provide uniform and balanced airflow through front and rear cards.

Embodiments described herein include cooling apparatuses and methods in conjunction with the embodiments of FIGS. 1 to 5, the cooling apparatuses and methods providing a uniform and balanced airflow on all system cards.

As described herein, air may be pulled in through a front or rear face of each “line,” “fabric,” or other system card to be used in systems described herein. Air drawn across the faces of the cards works to cool the optical transceivers and electronic circuitry with ambient (cool) air while hot air exhausted above the chassis apparatus. According to embodiments described herein, air flow is substantially uniform and balanced through the horizontal intake and vertical output of the chassis.

As described herein, redundant powered centrifugal blower fans may be located at a top of a chassis apparatus. Air flow balancing features within a center of the chassis apparatus provide uniform and balanced airflow through the line, fabric, system, and related cards.

As discussed herein, cooling air flow follows through a chassis apparatus in the direction illustrated in FIGS. 3 and 4. According to embodiments, as cool air is increased in temperature after being passed over heat-radiating components of various cards, hot air may be vented through the hollow section 150 of a chassis apparatus and redirected to the rear of the chassis apparatus into a duct or other exit strategy. In addition to this cooling architecture is a method to perform the same, with uniform and balanced cooling.

According to embodiments described herein, optical transceivers see cool air across the faces of the various cards. As illustrated in FIG. 5, various cards of a chassis apparatus 500 are designed with air vents 560 such as perforations in faceplates of cards 510 that allow air to be taken in.

FIG. 6 illustrates a chassis apparatus 600 having redundant blower fans 610 in accordance with embodiments described herein. The chassis apparatus 600 may use a rear exhaust solution, blowing warmed air from a rear 620 of the chassis apparatus 600. As illustrated in FIG. 6, the redundant blower fans 610 may be located above the hollow section 150 at a top of the chassis apparatus 600. The redundant blower fans 610 may pull exhaust air up the channel structure 160 and direct hot air out of the rear 620 of the chassis apparatus 600 through one or more exhaust air nozzles 630. The redundant blower fans 610 may be controlled by one or more blower fan controllers 615. For system level reliability purposes, redundant blower fans 610 are used to maintain cooling air circulation in the event of a single fan failure. The blower fan controller 615 may be part of a card. The redundant blower fans 610 and the blower fan controllers 615 are field replaceable parts of the system.

Because an uppermost line card 540 is closest to the redundant blower fans 610, the strength of the redundant blower fans 610 and thus the velocity V will be greater near the top of channel structure 160 than near the bottom thereof. Therefore, to balance and make the volumetric air flow substantially uniform through a plurality of system cards, front plate openings 560 may also be configured to have different sizes, smaller front plate openings closer to the air mover apparatus and larger front plate openings farther away from the air mover apparatus.

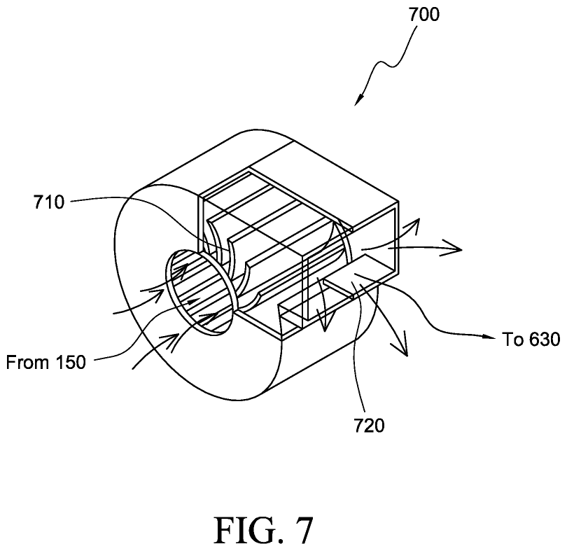

FIG. 7 illustrates a centrifugal blower fan 700 in accordance with FIG. 6. The centrifugal blower fan 700 may receive hot exhaust air from the channel structure 160 within the hollow section 150 into a fan wheel 710. The fan wheel 710 turns the air ninety degrees relative to the input stream. The heated air is then blown out of output 720 to one or more exhaust air nozzles 630. The centrifugal blower fan 700 may be embodied in different manifestations and in compact form factors.

To enable each system card to receive substantially uniform and balanced air flow, each vertical and horizontal stacked opening, in line with each system card includes airflow balancing features. The airflow balancing features are physical opening restrictors in faces of the system cards to ensure a volumetric flowrate (Q=AV) is uniform throughout the system. Q represents volumetric air flow. A represents the cross-sectional area of a physical opening. V represents the air flow velocity. The dimensions of the channel structure 160 are tailored to make all card slots of a type (e.g., line card slots) experience the same volumetric air flow “Q” passing through them. Card slots of different types (i.e., line card, fabric card, control card, power supply, etc.) can have different target quantities of air flow.

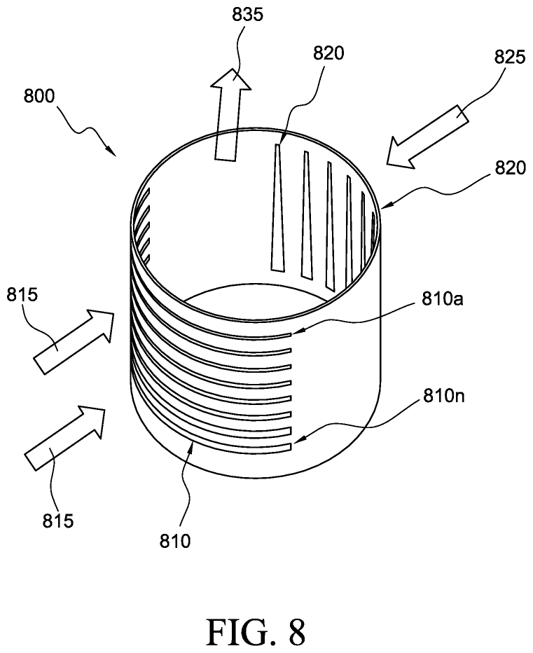

FIG. 8 illustrates a channel structure 800 to balance airflow throughout the system in accordance with embodiments described herein. The channel structure 800 may be used with any of the chassis apparatuses described herein. The channel structure 800 is disposed within the hollow section 150 of a chassis apparatus. The channel structure 800 may have a plurality of elongated air slots to coincide with air being pulled through the system cards.

For example, if a front part of chassis apparatus 100 is configured to have horizontally disposed line cards stacked one on top of another, the channel structure 800 placed within a hollow section 150 may have a first plurality of air slots 810. The first plurality of air slots 810 may receive air in an airflow direction 815 from a front of the chassis apparatus 100. The first plurality of air slots 810 may be narrower upper air slots 810a towards a top of the channel structure 800, and wider lower air slots 810n towards a bottom of the channel structure 800. The number of air slots n is not limited and may be chosen based on the height of the chassis and the number of card slots transferring air. The variance in width of the air slots is designed to let a varied amount of air into the channel structure to be vented upwards through the hollow section 150 of the chassis apparatus. Because the lower air slots 810n are farther away from an air mover apparatus, the velocity of air being drawn through the lower slots 810n is slower, and thus the lower air slots 810n are made larger such that the volumetric air flow Q through the lower air slots 810n will be equal to a volumetric air flow Q through upper air slots 810a. Upper air slots will have a greater velocity and a smaller volume. The width of air slots 810 may be varied from smaller to larger from upper slots 810a to lower slots 810n. Further, the widths of the slots 810 may be adjusted based upon the cooling needs of the system card cooled by the adjacent slot 810.

Depending on a configuration of a chassis apparatus, whether line cards, fabric cards, server blades, or other types of cards are installed, and depending on the orientation of these elements, the air slots may be disposed in a horizontal or vertical configuration. When vertical slots such as a second plurality of slots 820 are used, the vertical slots may have a width that varies from the top to the bottom of the slots 820. The second plurality of air slots 820 may receive air in an airflow direction 825 from a rear of the chassis apparatus 100. The second plurality of slots 820 are narrowest near the top of a hollow section 150 closest to an air mover and widest near a bottom of the hollow section 150, farthest from an air mover apparatus that draws hot air from the bottom of the chassis apparatus. This width variation is set so that the volume of air moving across the system card in the vertical direction is substantially uniform. Air flow from air flow directions 815 and 825 may merge in the channel structure 800 and be vented upwards in an airflow direction 835 out of the chassis apparatus 100.

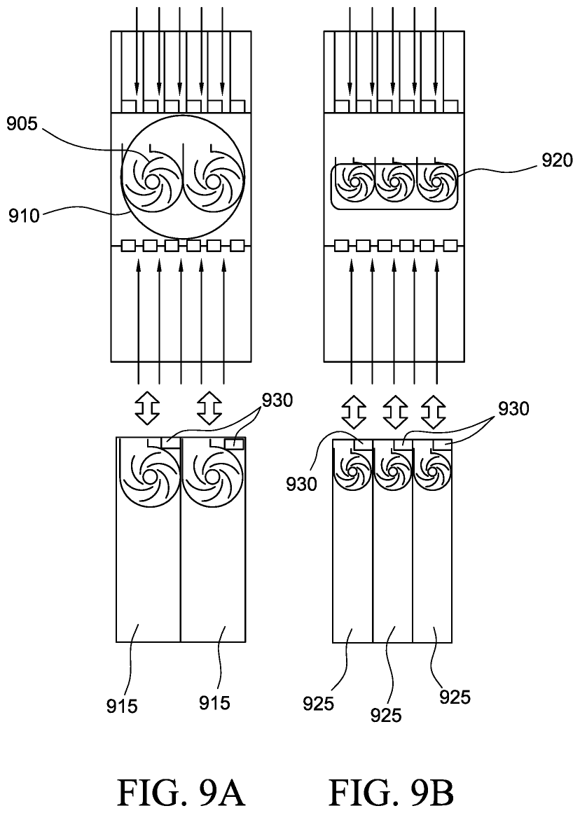

FIGS. 9A and 9B illustrates examples of a multi blower fan trays used in either a cylindrical center channel structure or a rectangular channel structure in accordance with embodiments described herein. According to embodiments described herein, a channel structure may have various shapes such as rectangular, square, circular, or another polygon. FIG. 9A illustrates a channel structure 910 having a circular shape. The circular channel structure 910 may have two redundant blower fans 905 disposed at a top section thereof, but designs are not limited thereto. Two or more redundant blower fans 905 may be used with a circular channel structure. The circular channel structure 910 may encompass the redundant blower fans 905, or the redundant blower fans 905 may be in a separate compartment above the circular channel structure 910. The redundant blower fans 905 may be loaded into a chassis apparatus 600 on removable fan trays 915. The fans may include a connector 930 that provides power and/or control signals to the blower fans 905.

FIG. 9B illustrates a channel structure 920 having a rectangular shape. The rectangular channel structure 920 may have three blower fans 930 disposed therein. If more blower fans are used, smaller fans may be used to align the blower fans within a vertical column of the hollow section 150. Alternatively, fewer smaller fans with greater power ratings may be used. The number of blower fans 930 is not limited to three if used with a rectangular channel structure. The number may be more or less depending on the system impedance, the size of the fans, the power of the fans, and the size of the channel structure. The blower fans may be loaded in the chassis apparatus 600 on removable fans trays 925.

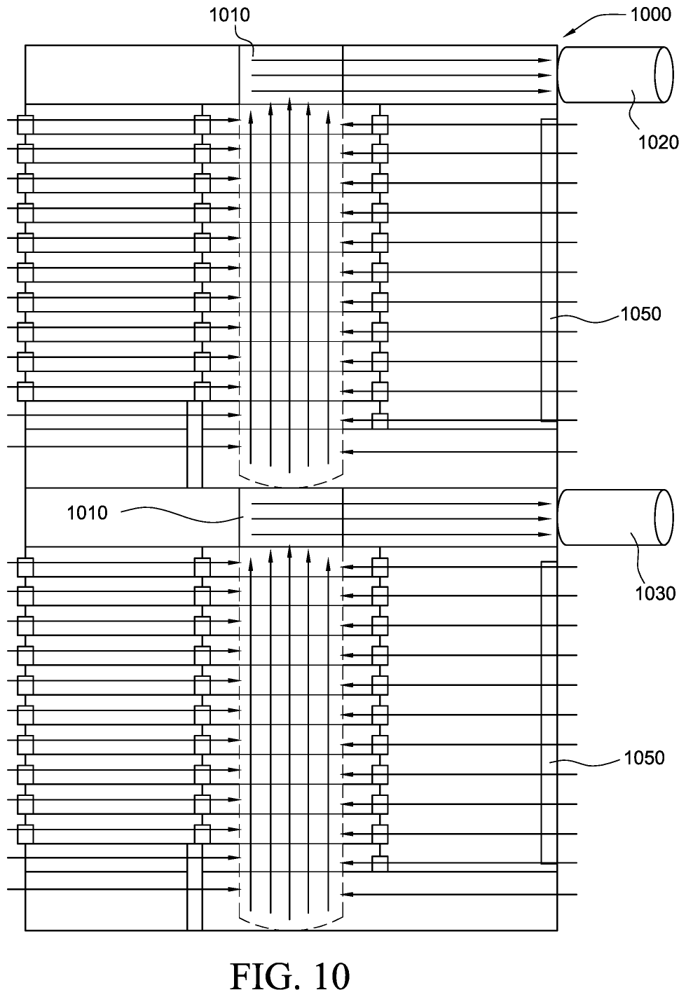

FIG. 10 illustrates a multi-shelf chassis apparatus 1000 in accordance with embodiments described herein. For customers wishing to install two or more separate systems within a single rack, there are no deployment restriction, and blower fans may be used. The multi-shelf chassis apparatus 1000 may be made up of two or more chassis apparatuses 1050. Each chassis apparatus 1050 functions independently of the other, routing air through separate channel structures, and venting heated air through separate ducts 1020 and 1030. Air exhausted through ducts 1020 and 1030 may be further vented away from the multi-shelf chassis apparatus 1000.

As described herein for a single chassis apparatus, air for the multi-shelf chassis apparatus is pulled in through the front face of each system card, cooling the optical transceivers with ambient (cool) air which is heated and exhausted at the top of the multi-shelf chassis apparatus 1000. Embodiments described herein may use a “chimney effect” in which there is a natural buoyant force of gases (PV=nRT). Hot air is aggregated into the middle of the stacked chassis apparatuses described herein through the suction of fans at the top of the chassis apparatuses in addition to the natural buoyant forces of air.

Because of the variable area of the air taken in through the faces and entered into the channel structure, the air flow across the system cards may be substantially uniform and balanced through the vertical height of the chassis apparatus.

Because of the design of the system, hot air is aggregated into a smaller area than traditional systems. Traditional systems exhaust into large areas such as a “hot aisle” behind the rear of a chassis. As heat is aggregated into a smaller area, the hot air may be directed or ducted away from system directly into local HVAC ducting to remove waste heat from central office or datacenter aisles.

Redundant blower fans 1010 may turn the airflow ninety degrees relative to the intake stream through the channel structure. For customers that prefer hot air to exhaust at the rear of the chassis apparatus, centrifugal blower fans may provide this airpath, which may result in lower fan power requirements and lower system power requirements over traditional systems.

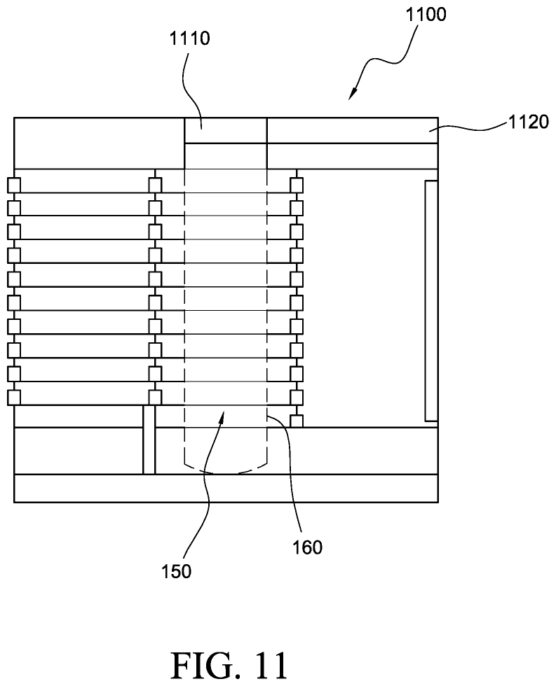

FIG. 11 illustrates axial air movers 1110 such as redundant axial fans in conjunction with a chassis apparatus 1100 according to embodiments described herein. Redundant axial fan trays 1110 may be used to exhaust air through a channel structure 160 of chassis apparatus 1100.

As illustrated in FIG. 11, the redundant axial fan trays 1110 may be located directly above the hollow section 150, providing a “chimney like” solution that may pull ambient cold air through variable sized openings in the faceplates having optical transceivers and other circuitry to exhaust hot air through the opening above the hollow section 160. Each redundant axial fan tray 1110 may be controlled by a fan controller card 1120. In the chassis apparatus 1100 having redundant axial fan trays 1110, air is vented through a top portion of the chassis apparatus 1100 to be carried away by additional ductwork (not illustrated).

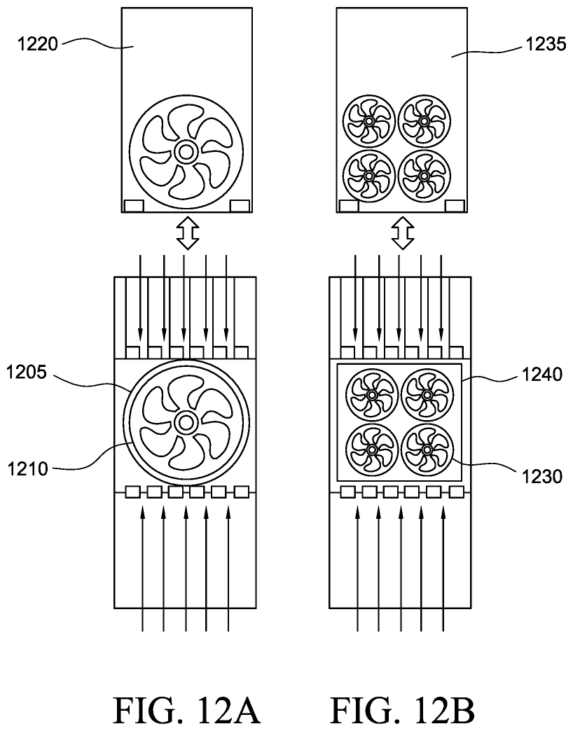

FIGS. 12A and 12B illustrate examples of fan trays with cylindrical and rectangular center channels in accordance with FIG. 11. According to embodiments described herein, a channel structure may have various shapes such as rectangular, square, circular, or another polygon. FIG. 12A illustrates a channel structure 1210 having a circular shape. The circular channel structure 1210 may be a single axial fan 1205 disposed at a top section thereof, but designs are not limited thereto. One or more axial fans 1205 may be used with the circular channel structure 1210. The circular channel structure 1210 may encircle the axial fan 1205, or the axial fan 1205 may be in a separate compartment above the circular channel structure 1210. The axial fan 1205 may be loaded into a chassis apparatus 1100 on a removable fan tray 1220.

FIG. 12B illustrates a channel structure 1230 having a square shape. The square channel structure 1230 may have four axial fans 1240 disposed therein. If more axial fans are used, smaller fans may be used to align the blower fans within a vertical column of the hollow section 150. Alternatively, fewer smaller fans with greater power ratings may be used. The number of axial fans 1240 is not limited to four if used with a square channel structure. The number may be more or less depending on the size of the fans, the power of the fans, and the size of the channel structure. The axial fans may be loaded in the chassis apparatus 1100 on a removable fan tray 1235.

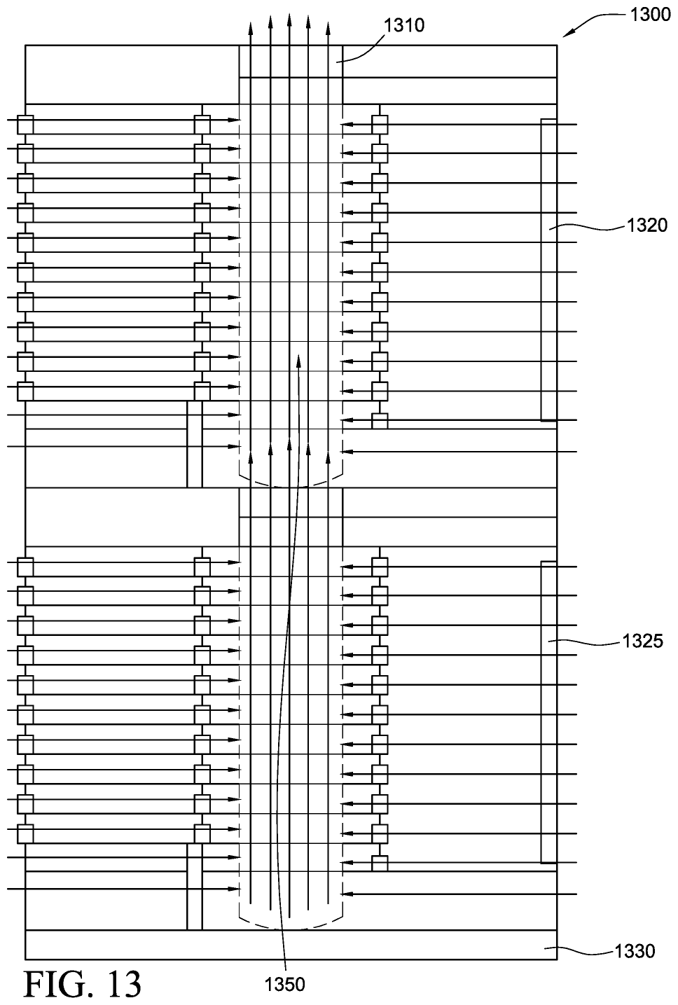

FIG. 13 illustrates stackable axial blower chassis rack 1300 in accordance with embodiments described herein. For customers wishing to co-locate two or more separate systems within a single rack, each chassis apparatus 1320 and 1325 may include a removable plate 1330 to block a bottom end of a vertical air channel. With more than one chassis apparatus deployed in a chassis rack 1300, the removable plate 1330 may be removed from each chassis apparatus 1320 (and any other stacked above chassis apparatus 1325) except the bottom most chassis apparatus in the chassis rack 1300. As a result, one continuous hollow section 1350 may be created from the combination of multiple chassis apparatuses 1320 and 1325. The number of stacked chassis apparatuses in a chassis rack 1300 are not limited to two but may include two or more stacked on top of each other given there is sufficient ceiling space in an installation. Redundant trays 1310 of each chassis apparatus 1320 and 1325 work together to pull and push air up the hollow section 1350 to the top of the upper most chassis apparatus 1320, to be vented away from the chassis rack 1300. Any of the axial fan arrangements described herein may be used with the chassis rack 1300

The stacked axial fan arrangement may provide various features. Air is pulled in through the front face of each “line” and “fabric” card, cooling the optical transceivers with ambient (cool) air and exhausted at the top of the chassis apparatus.

Embodiments described herein use the natural buoyant forces of gases (PV=nRT). Hot air is aggregated into the middle of the chassis apparatus through the suction of redundant fan trays 1310 at the top of the chassis rack 1300 in addition to the natural buoyant forces of air. Taking advantage of the natural buoyant flow of warm air, embodiments will result in lower fan power requirements and hence lower system power requirements. As described herein, airflow is substantially uniform and balanced through the vertical height of the chassis rack 1300.

With the stackable blower and axial fan chassis, a central fan unit (CFU) may be used regarding stackability for multiple chassis apparatuses in a rack. Hot air is pulled into the center of the chassis apparatus and exhausted through the top.

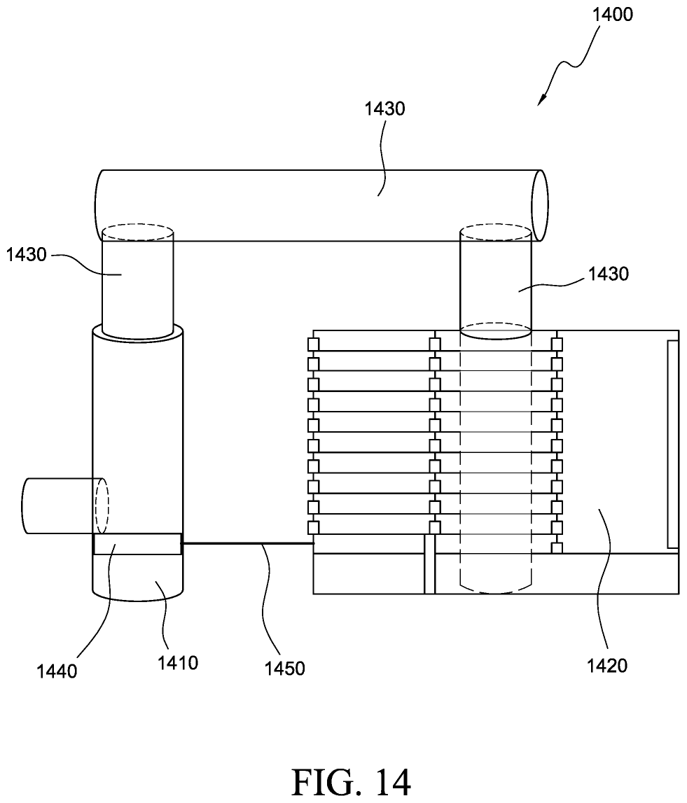

FIG. 14 illustrates a chassis system 1400 including a chassis apparatus driven by a CFU in accordance with embodiments described herein, but embodiments are not limited thereto. The CFU and connecting ductwork may be connected to stacked chassis racks as described herein. Embodiments place a CFU 1410 air mover solution in a separate location from a system chassis apparatus 1420. The CFU 1410 and the chassis apparatus 140 are connected together with ductwork 1430 (for air movement) and a wired or wireless connection 1450 for controllability. Controllability may be determined by control cards 1440 disposed in the CFU 1410.

The CFU 1410 air flow intensity may be controlled via the wired or wireless connection 1450 to the chassis system 1400 control cards 1440. Based on system requirements and environmental circumstances the CFU 1410 flow rate can be set accordingly. FIG. 14 illustrates a chassis apparatus 1420 where the ductwork 1430 is connected to the top and configured to direct exhaust air away from the immediate chassis apparatus 1420 area.

A CFU can use large or a higher quantity of fans and operate the fans within their normal operational limits, thereby increasing useful life and reducing fan service requirements.

A traditional system, after several years of generational, higher power card upgrades, may hit cooling limitations due to the constrained form-factor of the integrated fan solution. A CFU could be upgraded with a larger unit if necessary and increase the longevity of the chassis apparatus.

Embodiments described herein places a CFU air mover solution in a separate location from the chassis apparatus. Mechanical features within the center of the chassis apparatus provide uniform and balanced airflow through system cards such as “line” and “fabric” cards. The CFU may be redundant or spared to provide the necessary reliability

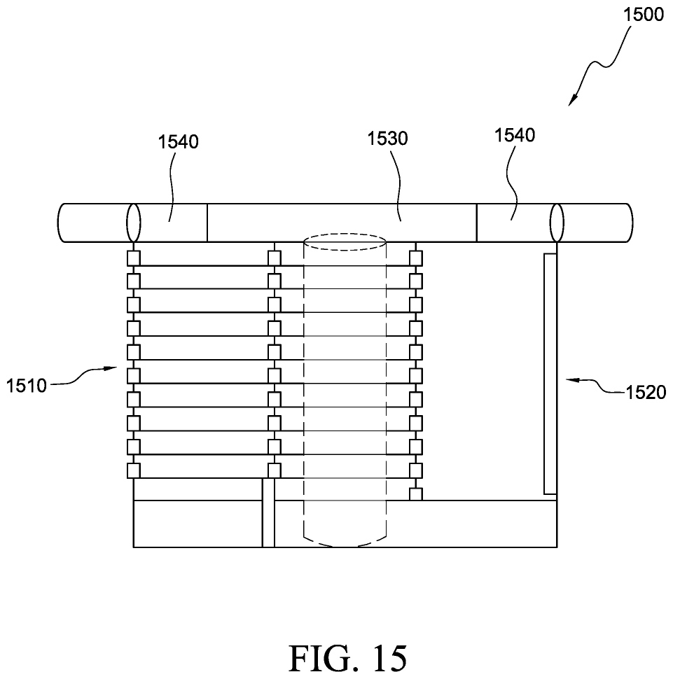

FIG. 15 illustrates a stackable variant of a chassis system 1500 driven by a CFU in accordance with embodiments described herein. FIG. 15 illustrates a variant of the chassis apparatus where exhaust air can be channeled to the front 1510 and/or rear 1520 of the system. This allows multiple chassis apparatuses of this type to be vertically stacked in the same rack and allows optional stackability for multiple chassis in a rack. A top section 1530 that comprises a horizontal channel and exhaust air nozzles 1540 can be an optionally installed module for the system.

According to embodiments, most of the system noise may be in the room containing the CFU 1410. This may allow operators and technicians to interact with one or more chassis apparatuses in a quiet and safe to-the-ears environment.

The CFU 1410 and ductwork 1430 takes up none of the rack space in the data center or central office. The CFU 1410 and ductwork 1430 can be of any size, which unbounds the performance and reliability of the fan. For example, large, high-powered systems can require a significant amount of high velocity air to pass through it.

For system level reliability purposes, the CFU 1410 may have a redundant capability. This could take of form of two CFUs 1410 that draw air from a common duct. Other options are possible.

By moving the CFU 1410 to a different room than a chassis apparatus 1420, the chassis system 1400 addresses concerns regarding acoustic noise, rack space, and scalability. According to embodiments, because the CFU 1410 is disposed in another room than one or more chassis apparatuses 1420, acoustic noise is minimized in the surrounding area of the chassis apparatuses 1420 to meet European Telecommunications Standards Institute (ETSI) and GR-63 acoustical limits. Since the main source of noise, the air mover, is in another room, the remaining chassis apparatus emits very little noise. Technicians are more likely to service the chassis apparatus than the CFU so exposure to high noise environments is reduced. This enhances safety and work place comfort.

Also, rack space for system functions may be maximized to make use of the installation area (e.g., datacenter, central office). The air mover solution no longer takes up rack space. That freed-up space can be used to install more line cards, fabric cards, server blades, etc.

Also, with the separate arrangement of parts, air mover solutions are scalable, have high performance, and are reliable. Because the CFU is not in the chassis apparatus, it is no longer bound by the traditional physical constraints.

Because the chassis systems 1400 and 1500 may use the chassis apparatus designs described herein, air flow may be substantially uniform and balanced through the vertical height of a chassis apparatus. Cards of the same type may see an equivalent air flow across each card slot.

According to embodiments described herein, hot air is aggregated into a smaller cross-sectional area than traditional systems. Traditional systems exhaust into large areas such as “hot aisle” behind the rear of the chassis apparatus. Aggregating the heat into a smaller area may allow the hot air to be directed or ducted away from system directly into local HVAC ducting to remove waste heat from Central Office or Datacenter aisles.

Embodiments described herein also include a configuration to duct warm air away from the chassis apparatuses that provides additional acoustic, space, and performance options.

The air flow is substantially uniform and balanced through the vertical height of the chassis apparatus. Cards of the same type see a substantially equivalent air flow across each card slot.

The chassis apparatus design described herein can lead to lower component costs. By drawing ambient air across the front face of both “line” cards and “fabric” cards compared to alternatives, costs can be reduced by using cheaper heatsinks to cool components, and deploying low temperature, low cost optical transceivers. Power consumption may be reduced because lower temperature components draw and dissipate less power than higher temperature components. In accordance with embodiments described herein, chassis apparatus cards may be mounted close enough together to allow a very short, low-loss electrical connection between the two end points.

Embodiments provided herein may lower material cost and dictate higher performance. Short, low loss electrical connections reduce system cost, size, and complexity when implementing high speed (i.e., gigabits per second) serial signaling. This is true for reasons including avoiding exotic and expensive PCB materials that would otherwise be required to “buy back” signal margin, and eliminating or requiring fewer electrical repeaters for the longest connections that require more PCB space, power, and cost.

It is possible to design “line” cards that work both in the system described herein and in a traditional orthogonal-direct system provided line card connector placement is compatible. This may allow a single line card form factor to be compatible with a range of router/switches from very small to very large multi-shelf configurations. This provides a market advantage for customers who can start with a small chassis apparatus and switch to a larger chassis apparatus in the future while leveraging their investment in expensive “line” cards.

Embodiments described herein direct hot exhaust air through the middle and out of the top of a rack/chassis apparatus, rather than into the traditional “hot aisle” behind the rear of the chassis apparatus. As large router/switch system power is in the tens of kilowatts, hot air management has become a limiting factor for customers trying to evacuate hot air from the “hot aisle.” By directing air out of the top of the rack, customers can install vents directly into front faces of the chassis apparatus, thus evacuating the air immediately from the installation center (data-center, central office, etc.). Also, as described herein, air may be routed from a room including a chassis apparatus to an external room where many fan members are housed and operated.

Although the various examples of one embodiment have been described in detail with reference to certain exemplary aspects thereof, it should be understood that embodiments described herein are capable of other embodiments and its details are capable of modifications in various obvious respects. As is apparent to those skilled in the art, variations and modifications can be affected while remaining within the spirit and scope of the embodiments. Accordingly, the foregoing disclosure, description, and figures are for illustrative purposes only and do not in any way limit the invention, which is defined only by the claims.

1. An apparatus, comprising:
a front section having at least one first card wherein the at least one card is configured to receive ambient air through a face thereof;
a rear section having at least one second card wherein the at least one second card is configured to receive ambient air through a face thereof;
a middle section disposed between the front section and the rear section; and
a channel structure within the middle section configured to vent air out of the apparatus.

2. The apparatus of claim 1, wherein the channel structure is configured to vent air from a lower portion of the middle section to an upper portion of the middle section.

3. The apparatus of claim 1, wherein the channel structure is configured to pull air out of the front section and the rear section.

4. The apparatus of claim 1, wherein the front section includes a first plurality of cards oriented horizontally and the rear section includes a second plurality of cards oriented vertically.

5. (canceled)

6. The apparatus of claim 5, wherein different cards of the at least one first card vent different volumes of air therethrough.

7. The apparatus of claim 1, comprising a midplane in the middle section, wherein the at least one first card is connected to the at least one second card through the midplane.

8. The apparatus of claim 1, wherein the at least one first card is not connected to the at least one second card through the middle section.

9. A chassis apparatus, comprising:
a first portion of the chassis apparatus configured to draw in air in a first direction;
a second portion of the chassis apparatus configured to draw in air in a second direction substantially opposite to the first direction; and
a third portion of the chassis apparatus configured to receive the air from the first direction and the second direction and channel the air in a third direction substantially perpendicular to the first direction and the second direction; and
a curved channel structure disposed in the middle portion, the curved channel structure having perforations to receive air from the front portion and the rear portion.

10. The chassis apparatus of claim 9, wherein the curved channel structure is configured to receive the air and exhaust it in the third direction.

11. The chassis apparatus of claim 9, wherein the first portion is configured to hold a first plurality of cards.

12. The chassis apparatus of claim 11, wherein the first plurality of cards each have first vents configured to receive ambient air to cool fronts of the first plurality of cards.

13. The chassis apparatus of claim 9, wherein the second portion is configured to hold a second plurality of cards.

14. The chassis apparatus of claim 13, wherein the second plurality of cards each have second vents configured to receive ambient air to cool fronts of the plurality of cards.

15. The chassis apparatus of claim 13, wherein the second plurality of cards have optical transceivers disposed on respective faces thereof and each optical transceiver receives substantially a same amount of air.

16. The chassis apparatus of claim 9, wherein the third portion includes a channel structure having a plurality of perforations configured to receive air from the first direction and the second direction and direct it upwards.

17. The chassis apparatus of claim 9, comprising a wire mesh disposed in the third portion to connect electrical components in the first portion to electrical components in the second portion.

18. The apparatus of claim 1, wherein the channel structure includes perforations to correspond to the front section and the rear section respectively.

19. The chassis apparatus of claim 9, wherein the first portion and the second portion are disposed at the same vertical level.

20. The chassis apparatus of claim 9, wherein the perforations are elongated around a portion of the curved channel structure.

21. The chassis apparatus of claim 9, wherein the perforations vary in size from one end of the curved channel structure to another.
